(19) United States
(12) Patent Application Publication
(10) Pub. No.: US 2013/0248237 A1
(43) Pub. Date: Sep. 26, 2013

(54) PRINTED CIRCUIT BOARD

(71) Applicants: JIE-SONG ZHOU, Shenzhen City (CN); XING-HUA TANG, Shenzhen City (CN)

(72) Inventors: JIE-SONG ZHOU, Shenzhen City (CN); XING-HUA TANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD ., Shenzhen City (CN)

(21) Appl. No.: 13/569,195

(22) Filed: Aug. 8, 2012

(30) Foreign Application Priority Data
Mar. 21, 2012 (CN) 201210075382.5

(51) Int. Cl. H05K 1/11

(52) U.S. Cl. 174/266

(57) ABSTRACT

A printed circuit board (PCB) includes at least two vias and at least two bonding pads corresponding to the vias. Each bonding pad is arranged on the surface of the PCB around the corresponding one of the at least two vias. Between two adjacent bonding pads, a through hole is arranged for preventing molten solder overflowing from one bonding pad to the other.

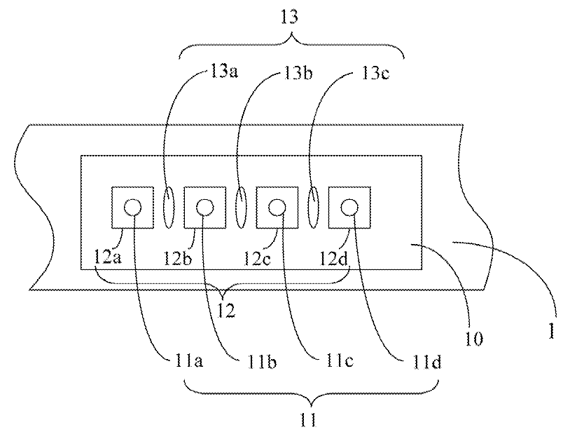

### BACKGROUND

1. Technical Field

The present disclosure relates to a printed circuit board (PCB) and, particularly, to a PCB that prevents adjacent bonding pads becoming short circuited.

2. Description of Related Art

Many components on a printed circuit board (PCB) are mounted using surface mount technology (SMT). Through-hole components (such as inductance coils, high-power components, power modules and so on) need to be mounted on the PCB by wave soldering or manual soldering. During the wave soldering or manual soldering, molten solder may fuse two adjacent bonding pads together and result in a short circuit.

### BRIEF DESCRIPTION OF THE DRAWING

The components of the drawing are not necessarily drawn to scale, the emphasis instead being placed upon clearly illustrating the principles of the present disclosure. Moreover, in the drawing, like reference numerals designate corresponding parts throughout.

The drawing is a partial schematic view of a PCB in accordance with an exemplary embodiment.

### DETAILED DESCRIPTION

The drawing is a partial schematic view of a PCB 1 in accordance with an exemplary embodiment. The PCB 1 includes at least one soldering area 10 where multi-pin through-hole components are to be soldered. The soldering area 10 includes multiple vias 11 allowing the pins of the through-hole components to pass through, and bonding pads 12 around the vias 11 arranged on the surface of the PCB 1 for soldering the through-hole components. A through hole 13 is arranged between every two adjacent bonding pads 12. During soldering, if the molten solder overflows, it will flow into the through hole 13 rather than flowing to an adjacent bonding pad, thereby avoiding forming a short circuit between two bonding pads. And after soldering, because of the through holes 13, it is easy for an operator to check and make sure there is no solder connecting two bonding pads.

As shown in the drawing, the PCB 1 is prepared to receive a four-pin through-hole component. There are four vias (11a, 11b, 11c, and 11d) and four bonding pads (12a, 12b, 12c, 12d). A through hole 13a is arranged between bonding pads 12a and 12b. A through hole 13b is arranged between bonding pads 12b and 12c. A through hole 13c is arranged between bonding pads 12c and 12d.

In the embodiment, the through-hole components are mounted on the PCB by wave soldering or manual soldering, and the shape of the through hole between each two adjacent bonding pads is rectangular or elliptic in cross-section,

Although the present disclosure has been specifically described on the basis of preferred embodiments, the disclosure is not to be construed as being limited thereto. Various changes or modifications may be made to the embodiment without departing from the scope and spirit of the disclosure.

What is claimed is:

1. A printed circuit board (PCB), comprising:
at least two vias; and
at least two bonding pads corresponding to the two vias where through-hole components are to be soldered, each bonding pad being arranged on the surface of the PCB around the corresponding one of the at least two vias; and
at least one through hole each arranged between two adjacent ones of the at least two adjacent bonding pads.

2. The PCB as described in claim 1, wherein each of the at least one through hole is rectangle-shaped.

3. The PCB as described in claim 1, wherein each of the at least one through hole is sllipse-shaped.
